(19) United States
(12) Patent Application Publication
(10) Pub. No.: US 2013/0168706 A1
(43) Pub. Date: Jul. 4, 2013

(54) PRINTED LIGHT EMITTING DEVICES AND METHOD FOR FABRICATION THEROF

(71) Applicants: Budiman Salam, Singapore (SG); Chee Wai Albert Lu, Singapore (SG); Boon Keng Lok, Singapore (SG); Lia Lal Wai, (US)

(72) Inventors: Budiman Salam, Singapore (SG); Chee Wai Albert Lu, Singapore (SG); Boon Keng Lok, Singapore (SG); Lia Lal Wai, (US)

(73) Assignee: AGENCY FOR SCIENCE, TECHNOLOGY AND RESEARCH, Singapore (SG)

(21) Appl. No.: 13/606,626

(22) Filed: Sep. 7, 2012

(30) Foreign Application Priority Data
Sep. 8, 2011 (SG) 201106475-5

(51) Int. Cl. H01L 33/08

(52) U.S. Cl. CPC H01L 33/08
USPC 257/88; 438/34

(57) ABSTRACT

An array of light emitting devices and a method for large area fabrication of such is provided. The method includes providing a continuous flexible substrate and printing one or more layers of light emitting devices comprised of layers of transparent conductor, light emitting material, dielectric and electrode on the flexible substrate. The array of light emitting devices includes a flexible substrate and one or more layers of light emitting devices on the flexible substrate. The one or more layers of light emitting devices include layers of transparent conductor, light emitting material, dielectric and electrode.

### CROSS-REFERENCE TO RELATED APPLICATION

The present application claims priority to Singapore Patent Application No. 201106475-5, filed 8 Sep. 2011.

### FIELD OF THE INVENTION

The present invention generally relates to light emitting devices, and more particularly relates to printed arrays of light emitting devices and the methods of fabricating the same.

### BACKGROUND OF THE DISCLOSURE

Conventional light emitting devices are manufactured in wafers and then sold separately. A manufacturer then purchases the devices, fabricates an array and encapsulates it in order to present a lighted display.

With the advance of manufacturing techniques, light emitting devices and other array devices such as solar cells can be manufactured in an array and encapsulated. However, this typically involves manufacturing arrays of interconnected devices that are no bigger than typical semiconductor wafers (200 mm or 300 mm).

Thus, what is needed is a scalable, easily manufacturable large area fabrication technique for arrays of devices such as light emitting devices. Furthermore, other desirable features and characteristics will become apparent from the subsequent detailed description and the appended claims, taken in conjunction with the accompanying drawings and this background of the disclosure.

### SUMMARY

According to the Detailed Description, a method for large area fabrication of an array of light emitting devices is provided. The method includes providing a continuous flexible substrate and printing one or more layers of light emitting devices comprised of layers of transparent conductor, light emitting material, dielectric and electrode on the flexible substrate.

In accordance with another aspect, an array of light emitting devices is provided. The array of light emitting devices includes a flexible substrate and one or more layers of light emitting devices on the flexible substrate. The one or more layers of light emitting devices include layers of transparent conductor, light emitting material, dielectric and electrode.

In accordance with yet another aspect, a printed light emitting device is provided. The printed light emitting device includes a flexible substrate, a first lighting array facing a first direction, and a second lighting array facing a second direction. The second direction is 180° separated from the first direction. The first array includes an array of first transparent conductors on the flexible substrate, an array of first light emitting materials on the array of transparent conductor, an array of first dielectrics on the array of first light emitting materials, and an array of first electrodes on the array of first dielectrics. The second lighting array includes an array of second electrodes on the flexible substrate, an array of second dielectrics on the array of second electrodes, an array of second light emitting materials on the array of second dielectrics, and an array of second transparent conductors on the array of second light emitting materials.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to illustrate various embodiments and to explain various principles and advantages in accordance with a present invention.

FIG. 1 illustrates a side planar view of a double sided printed light emitting device array in accordance with a first aspect of the present embodiment.

FIG. 2 illustrates a side planar view of fabrication of a double sided printed light emitting device array in accordance with a second aspect of the present embodiment.

FIG. 3 illustrates a side planar view of double sided printed light emitting device material in accordance with a third aspect of the present embodiment.

FIG. 4 illustrates a side planar view of double sided printed light emitting device material in accordance with a fourth aspect of the present embodiment.

FIG. 5 illustrates a side planar view of a single sided printed light emitting device array in accordance with a fifth aspect of the present embodiment.

FIG. 6 illustrates a side planar view of an alternate embodiment of the single sided printed light emitting device array of FIG. 5.

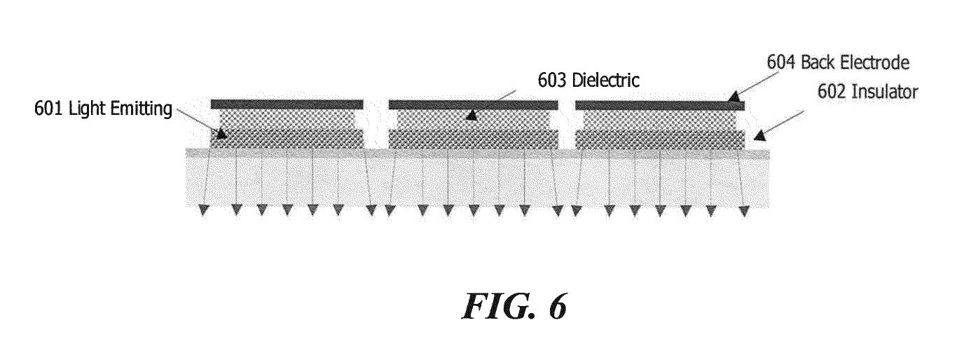

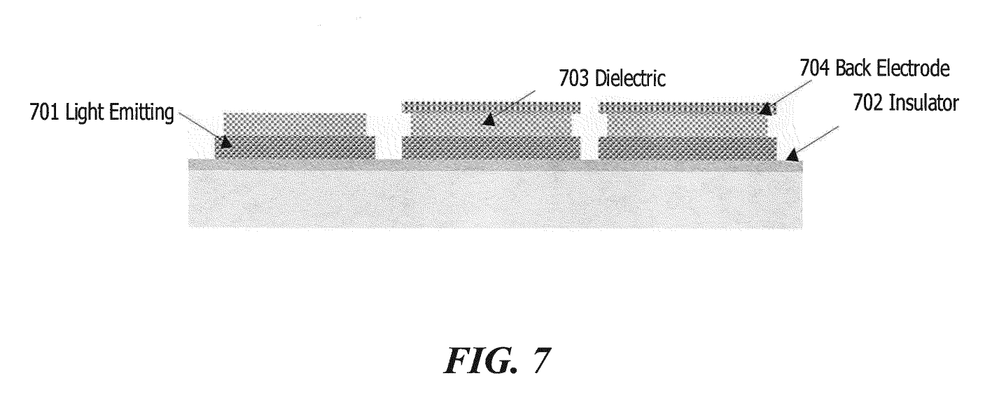

And FIG. 7 illustrates a side planar view of fabrication of the alternate embodiment of the single skied printed light emitting device array of FIG. 6.

Skilled artisans will appreciate that elements in the figures are illustrated for simplicity and clarity and have not necessarily been depicted to scale. For example, the dimensions of some of the device elements in the figures may be exaggerated in one dimension relative to another dimension to help to improve understanding of the present and alternate embodiments.

### DETAILED DESCRIPTION

The following detailed description is merely exemplary in nature and is not intended to limit the invention or the application and uses of the invention. Furthermore, there is no intention to be bound by any theory presented in the preceding background of the invention or the following detailed description. It is the intent of this invention to present printed light emitting device arrays and highly scalable methods for fabricating such to achieve both single-sided and two-sided light emitting device arrays with increased lifetime and mechanical robustness.

A patterned or hybrid-patterned combination of at least one transparent conductor is provided which includes at least one light emitting layer, at least one dielectric and at least one electrode and provides a printed light emitting device configured to provide single-sided or double-sided light emission from a patterned light emitting layer. A meshed-patterned electrode may be provided to reduce cost and flexible integration of the light emitting device with the electrode layer is provided for increased usability. The patterned light emitting layer may be encapsulated within the manufacturing thereof.

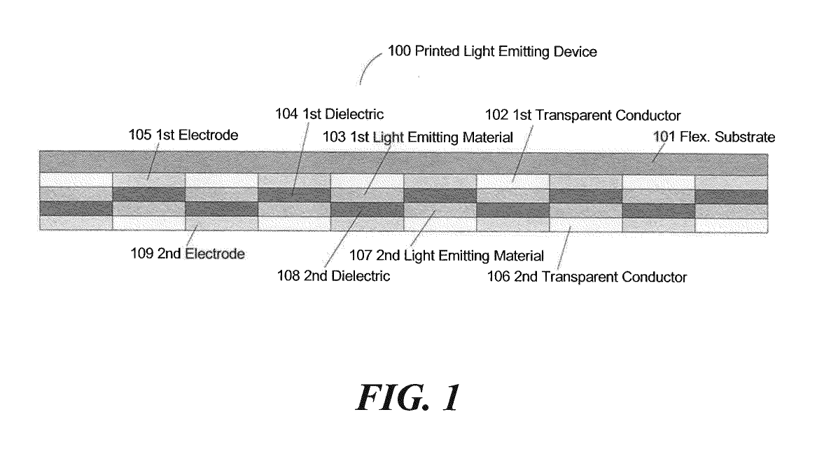

Referring to FIG. 1, there is provided a double-sided light emitting device 100 including patterned elements. The printed light emitting device 100 includes a flexible substrate 101 of any flexible substrate material such as polyethylene terephthalate (PET) or polycarbonate (PC) on which are printed patterned elements for a first-direction-facing lighting device and a second-direction-facing lighting device. The first-direction-facing lighting includes an array of first transparent conductors 102 patterned onto the flexible substrate 101, an array of first light emitting materials 103 patterned thereon and an array of second dielectrics 108 patterned on the array of first light emitting materials 103. An array of second electrodes 109 is patterned on the array of second dielectrics 108 to complete the first-direction-facing lighting device.

The second-direction-facing lighting device faces 180° opposite to the first-direction-facing lighting device and includes an array of first electrodes 105 patterned onto the flexible substrate 101. An array of first dielectrics 104 is patterned onto the array of first electrodes 105 and an array of second light emitting materials 107 is patterned onto the array of first dielectrics 104. Finally, an array of second transparent conductors 106 is patterned on the array of second light emitting materials 107.

The first and second transparent conductors 102, 106 are formed of transparent conductive materials such as conductive oxides (e.g. indium tin oxide (ITO) or zinc oxide (ZnO)), conductive polymers (e.g. PEDOT:PSS), carbon nanotubes or graphene. The first and second light emitting materials 103, 107 may be, for example, doped zinc sulfide. The first and second dielectrics 104, 108 may be a dielectric such as a barium titanate composite. And the first and second electrodes 105, 109 are formed of conductive material such as silver or copper. In this manner, the double-sided printed light emitting device 100 is provided for use in displays, advertising, or other visual uses.

The double-sided printed light emitting device 100 can advantageously be manufactured in a continuous printing process which makes both small and large displays easily manufacturable. A method for continuous manufacturing of the printed double-sided light emitting device 100 includes providing a continuous coil of the flexible substrate 101 and printing first transparent conductors 102 in a first pattern on the flexible substrate 101, then printing first electrodes 105 in a second pattern on the flexible substrate 101. The first light emitting materials 103 are printed over the array of transparent conductors 102, while the first dielectrics 104 are printed over the array of first electrodes 105. Next, the second dielectrics 108 are printed over the array of first light emitting materials 103 and the second light emitting materials 107 are printed over the array of first dielectrics 104. Finally, the second electrodes 109 are printed over the array of second dielectrics 108 and the second transparent conductors 106 are printed over the array of second light emitting materials 107. In this manner, the double-sided light emitting device 100 can be scalably manufactured in a continuous printing process, enabling large area processing of the double-sided light emitting device 100.

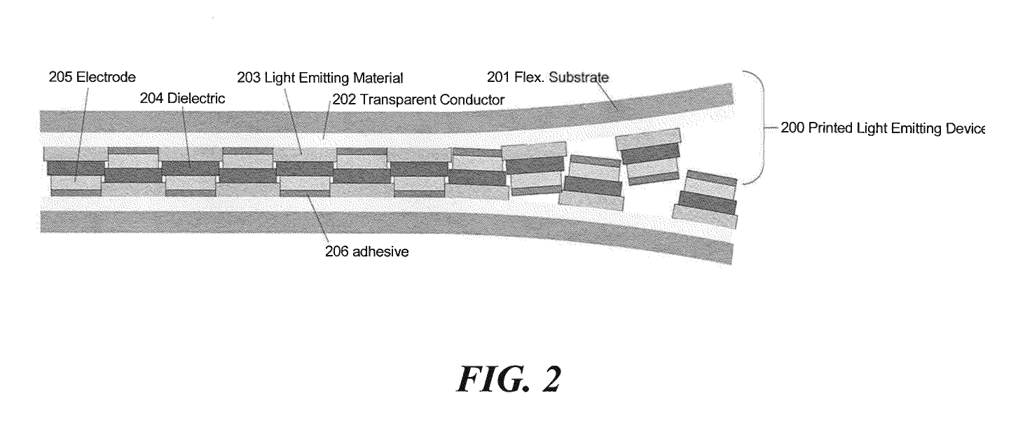

Referring next to FIG. 2, a side planar view of fabrication of a double-sided printed light emitting device array from two single-sided printed light emitting devices 200 in accordance with a second aspect of the present embodiment is depicted. The double-sided light emitting device includes two laminated layers of single-sided light emitting devices 200 which overlap each other when laminated together.

Each light emitting device 200 includes a continuous coil of a flexible substrate 201, transparent conductors 202 adjacent the flexible substrate 201, and an array of light emitting materials, 203 adjacent an array of transparent conductor 202. Each light emitting device 200 further includes an array of dielectrics 204 adjacent the array of light emitting materials 203 wherein the elements of the array of dielectrics 204 have a dimension that is smaller than elements of the array of light emitting materials 203. In addition, each light emitting device 200 includes an array of electrodes 205 adjacent the array of dielectrics 204 which each have a dimension that is smaller than the elements of the array of dielectrics 204. Finally, an array of adhesives 206 is adjacent the array of electrodes 205 which each have a dimension that is smaller than the elements of the array of dielectrics 205 and are provided to laminately adhere the two light emitting devices 200 to each other.

A method of manufacturing the laminated double-sided printed light emitting device includes the steps of printing two light emitting devices 200, each printed on the continuous coil of a flexible substrate 201, with the transparent conductors 202 printed on the flexible substrate 201, the light emitting materials 203 printed on the transparent conductor 202, the dielectrics 204 printed on the array of electrodes 203, and the array of electrodes 205 printed on the array of dielectrics 204. The adhesives 206 are printed on the array of electrodes 205 and the two light emitting devices are aligned such that the array of adhesives 206 face the transparent conductor 202 and couple the two light emitting devices together during lamination as illustrated in FIG. 2.

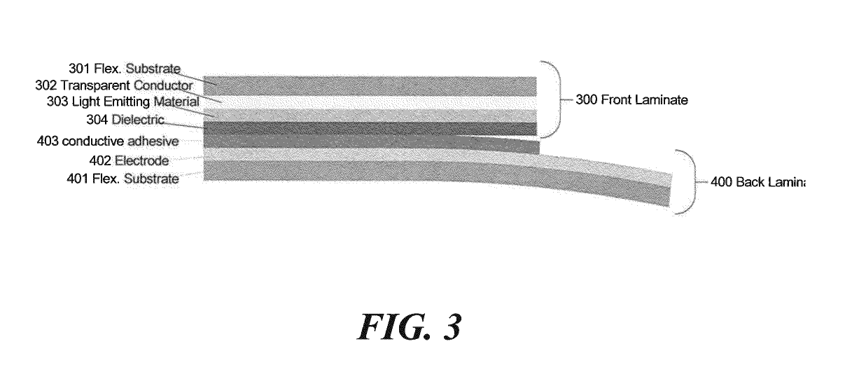

Referring to FIG. 3, there is provided a single-sided and double-sided light emitting device with integrated electrical interconnection. A first (or front) laminate 300 includes a continuous coil of a first flexible substrate 301 and a transparent conductor 302 adjacent the first flexible substrate 301. A light emitting material 303 is provided adjacent the transparent conductor 302 and a dielectric layer 304 is provided adjacent the light emitting material 303.

A second (or back) laminate 400 similarly includes a second flexible substrate 401, an electrode layer 402, and a conductive adhesive 403 such as a silver particle filled polymer. The layers 300, 400 are laminated together with the interconnection for the array of devices in the first laminate layer being provided in the electrode layer of the second laminate layer 400.

This combined interconnection layer and single- or double-sided light emitting device can advantageously be manufactured in a single printing process. For example, the printed light emitting device as shown in FIG. 3 can be manufactured by providing a first (or front) laminate 300 which has been printed on a continuous coil of a first flexible substrate 301 by printing transparent conductors 302 on the first flexible substrate 301, printing light emitting materials 303 on the transparent conductor 302, and printing dielectrics 304 on the light emitting materials 303. A second (back) laminate 400 which has a dimension larger than that of the first laminate 300 is provided by printing on a continuous coil of a second flexible substrate 401 conductors 402 printed on the second flexible substrate 401 and a conductive adhesive 403 printed on the conductors 402. The first laminate 300 and the second laminate 400 are then coupled together to provide interconnection for the array of light emitting devices. Those skilled in the art can realize that this manufacturing process described for single-facing light emitting devices can easily be adapted for double-sided light emitting devices.

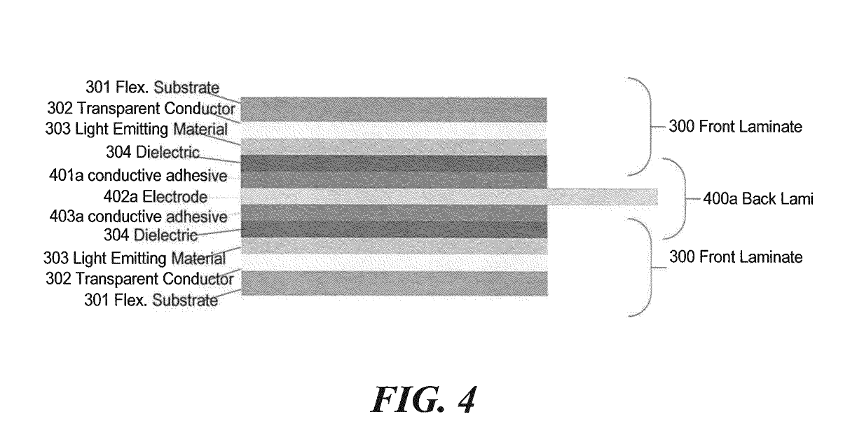

Referring next to FIG. 4, there is provided another embodiment of a double-sided light emitting device. The light emitting device includes two single-sided front laminates 300 as described in FIG. 3 oriented in opposing directions. A back laminate 400a includes a conductive adhesive 401a, an electrode layer 402a, and a conductive adhesive 403a. The back laminate 400a is adhered between the two front laminates 300 to provide interconnection for both sides of the double-sided light emitting device.

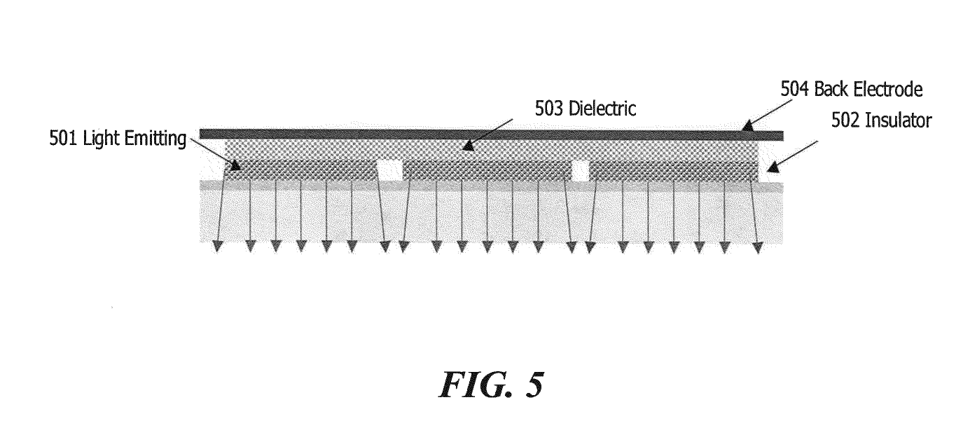

Referring to FIG. 5, a printed light emitting device is depicted which includes a front transparent conductive film 500a, a patterned light emitting layer 501a, a non-patterned insulator layer 502, a non-patterned dielectric layer 503, and a non-patterned back electrode 504. This highly scalable and robust printed light emitting device can be fabricated by printing the light emitting materials 501 on the transparent conductive film 500, printing the insulator layer 502 to fill gaps between the patterned light emitting pixels of the layer 501, printing the dielectric layer 503, and printing the back electrode 504. The insulator 502 between the blocks of light emitting material 501 enables patterned pixilated lighting from the light emitting material, while the insulator layer 502 at either side allows isolation of the light emitting device array and enables routing of circuitry at the edge of a lighting panel or between blocks of pixels in a panel.

Referring to FIG. 6, another embodiment is provided for a single-sided light emitting device which has at least one patterned light emitting layer, at least one patterned dielectric, patterned electrode and at least one non-patterned transparent conductor. This embodiment enables a robust pixilated display where the electrodes and dielectrics are individually connected to the light emitting material.

The printed light emitting device as shown in FIG. 6 includes a front transparent conductive film 600, a patterned light emitting layer 601, and a non-patterned insulator layer 602. A patterned dielectric layer 603 has a surface area smaller than a surface area of the patterned light emitting layer 601, and a patterned back electrode 604 is formed thereon. An improved method for manufacturing this printed light emitting device would include printing the light emitting materials 601 on the transparent conductive film 600, printing the insulator layer 602 to fill gaps between the patterned light emitting pixels of the layer 601, printing the dielectric layer 603, and printing the back electrode 604.

Referring to FIG. 7, there is provided a single-sided light emitting device having at least one patterned light emitting layer 701, at least one patterned dielectric 703, at least one meshed-patterned electrode 704 and at least one non-patterned transparent conductor 700. A method for manufacturing this light emitting device, advantageously includes printing the light emitting materials 701 on the transparent conductive film 700, printing the insulator layer 702 to fill gaps between the patterned light emitting pixels of the layer 701, printing the dielectric layer 703, and mesh-printing the back electrode 704. The mesh-printed back electrode 704 provides cost reduction due to use of less conductive material such as expensive copper or silver. In addition, the mesh-printed hack electrode 704 allows light from the light emitting materials 701 to emit from the hack side of the display when the dielectric material 703 is transparent.

Thus it can be seen that a novel patterned or hybrid-patterned combination of at least one transparent conductor, at least one light emitting layer, at least one dielectric and at least one electrode has been provided. Also proposed is a flexible integration of a light emitting device with an electrode layer. There may be provided a printed light emitting device configured to provide double-sided light emission from a patterned light emitting layer. Advantageously, the patterned light emitting layer may be encapsulated such that the printed light emitting device has increased lifetime and mechanical robustness. Also, a meshed-patterned electrode may be provided, thereby reducing cost and, possibly, providing multi-sided illumination. Embodiments of the present printed light emitting device can provide large area lighting, large area signage, or large area display, under both indoor and outdoor conditions. While several exemplary embodiments have been presented in the foregoing detailed description of the invention, it should be appreciated that a vast number of variations exist.

It should further be appreciated that the exemplary embodiments are only examples, and are not intended to limit the scope, applicability, dimensions, or configuration of the invention in any way. Rather, the foregoing detailed description will provide those skilled in the art with a convenient road map for implementing an exemplary embodiment of the invention, it being understood that various changes may be made in the function and arrangement of elements and method of fabrication described in the exemplary embodiments without departing from the scope of the invention as set forth in the appended claims.

What is claimed is:

1. A method for large area fabrication of an array of light emitting devices, the method comprising the steps of:
providing a continuous flexible substrate; and
printing one or more layers of light emitting devices comprised of layers of transparent conductor, light emitting material, dielectric and electrode on the flexible substrate.

2. The method in accordance with claim 1 wherein the step of printing one or more devices comprises:
printing first devices having the transparent conductor printed on the flexible substrate, with the other layers of the first devices printed as light emitting material on the transparent conductor, dielectric on the light emitting material, and electrode on the dielectric; and
printing second devices having the electrode printed on the flexible substrate, with the other layers of the second devices printed as dielectric on the electrode, light emitting material on the dielectric, and transparent conductor on the light emitting material.

3. The method in accordance with claim 1 further comprising:
printing a layer of adhesive on the top most layer of the one or more layers of light emitting devices.

4. The method in accordance with claim 3 wherein the one or more layers of light emitting devices are two layers of light emitting devices, the method further comprising:
laminating the two layers of light emitting devices using the adhesive.

5. The method in accordance with claim 1 wherein the step of printing one or more devices comprises printing one or more layers of light emitting devices comprised of layers of transparent conductor, light emitting material, dielectric and mesh electrode on the flexible substrate.

6. The method in accordance with claim 1 further comprising:
printing an electrode layer for interconnecting each device of the one or more layers of light emitting devices.

7. The method in accordance with claim 6 wherein the step of printing the electrode layer comprises printing the electrode layer sandwiched between a flexible substrate and an adhesive layer, the method further comprising laminating the adhesive layer to the one or more layers of light emitting devices.

8. The method in accordance with claim 1 wherein the step of printing one or more devices comprises printing the light emitting material layer patterned to provide gaps between adjoining light emitting devices, the method further comprising printing insulative material to fill the gaps between adjoining light emitting devices.

9. An array of light emitting devices comprising:
a flexible substrate; and
one or more layers of light emitting devices comprised of layers of transparent conductor, light emitting material, dielectric and electrode on the flexible substrate.

10. The array in accordance with claim 9 wherein the one or more layers of light emitting devices comprise:
first devices having the transparent conductor printed on the flexible substrate, with the other layers of the first devices printed as light emitting material on the transparent conductor, dielectric on the light emitting material, and electrode on the dielectric; and
second devices having the electrode primed on the flexible substrate, with the other layers of the second devices printed as dielectric on the electrode, light emitting material on the dielectric, and transparent conductor on the light emitting material.

11. The array in accordance with claim 9 further comprising:
a layer of adhesive on the top most layer of the one or more layers of light emitting devices.

12. The array in accordance with claim 11 wherein the one or more layers of light emitting devices comprise:
a first layer of light emitting devices; and
a second layer of light emitting devices laminated to the first layer of light emitting devices by the adhesive.

13. The array in accordance with claim 9 wherein the electrode layer comprises a layer of mesh electrode.

14. The array in accordance with claim 9 further comprising an additional electrode layer for interconnecting each device of the one or more layers of light emitting devices.

15. The array in accordance with claim 14 further comprising a flexible substrate and an adhesive layer sandwiching the additional electrode therebetween, the adhesive layer used to laminate the one or more layers of light emitting devices together.

16. The array in accordance with claim 9 wherein gaps are formed between adjoining light emitting devices within the light emitting material layer, the array further comprising insulative material filling the gaps between the adjoining light emitting devices.

17. A printed light emitting device comprising:
a flexible substrate;
a first lighting array facing a first direction comprising:
an array of first transparent conductors on the flexible substrate;
an array of first light emitting materials on the array of transparent conductor;
an array of first dielectrics on the array of first light emitting materials; and
an array of first electrodes on the array of first dielectrics; and
a second lighting array facing a second direction, wherein the second direction is 180° separated from the first direction, the second lighting array comprising:
an array of second electrodes on the flexible substrate;
an array of second dielectrics on the array of second electrodes;
an array of second light emitting materials on the array of second dielectrics; and
an array of second transparent conductors on the array of second light emitting materials.
